(19) United States
(12) Patent Application Publication
(10) Pub. No.: US 2021/0305022 A1
(43) Pub. Date: Sep. 30, 2021

(54) EDGE RING, SUBSTRATE SUPPORT, PLASMA PROCESSING SYSTEM AND METHOD OF REPLACING EDGE RING

(71) Applicant: Tokyo Electron Limited, Tokyo (JP)

(72) Inventors: Hiroshi TSUJIMOTO, Miyagi (JP); Yusei KUWABARA, Miyagi (JP); Lifu LI, Miyagi (JP)

(73) Assignee: Tokyo Electron Limited, Tokyo (JP)

(21) Appl. No.: 17/195,728

(22) Filed: Mar. 9, 2021

(30) Foreign Application Priority Data
Mar. 24, 2020 (JP) 2020-053034

(51) Int. Cl. H01J 37/32; H01L 21/687; H01L 21/67; H01L 21/683

(52) U.S. Cl. CPC H01J 37/32642; H01J 37/32715; H01J 37/32807; H01J 2237/002; H01L 21/68742; H01L 21/67103; H01L 21/6833; H01L 21/68735

(57) ABSTRACT

A substrate support includes a substrate support surface on which a substrate is placed, a ring support surface on which an edge ring is placed to surround the substrate placed on the substrate support surface, and an electrode configured to attract and hold the edge ring on the ring support surface by an electrostatic force. A heat transfer sheet is attached to a surface of the edge ring facing the ring support surface, and the edge ring is placed on the ring support surface via the heat transfer sheet. A conductive film is formed on a surface of the heat transfer sheet facing the ring support surface. Further, the edge ring is held on the ring support surface by attracting and holding the conductive film of the heat transfer sheet attached to the edge ring onto the ring support surface by the electrostatic force generated by the electrode.

### CROSS-REFERENCE TO RELATED APPLICATION

This application claims priority to Japanese Patent Application No. 2020-053034, filed on Mar. 24, 2020, the entire contents of which are incorporated herein by reference.

### TECHNICAL FIELD

The present disclosure relates to an edge ring, a substrate support, a plasma processing system and a method of replacing the edge ring.

### BACKGROUND

Japanese Patent Application Publication No. 2016-119334 discloses that a heat transfer sheet having adhesiveness and softness is disposed between a focus ring (edge ring) and a substrate support disposed in a substrate processing apparatus.

A substrate processing apparatus disclosed in Japanese Patent Application Publication No. 2011-054933 includes a substrate support provided with a susceptor having a substrate support surface on which a substrate is placed and a focus ring support surface on which a focus ring is placed, and a plurality of positioning pins. The substrate processing apparatus includes a lifter pin(s) and a transfer arm. The lifter pin is provided in the substrate support so as to protrude beyond and retract below the focus ring support surface, and configured to lift the focus ring together with the respective positioning pins to be separated from the focus ring support surface. The transfer arm is provided outside the processing chamber and configured to exchange, in between the transfer arm and the lifter pin(s), the focus ring equipped with the positioning pins through a loading/unloading port provided at the processing chamber.

The substrate processing apparatus disclosed in Japanese Patent Application Publication No. 2016-122740 includes a plurality of electrodes and a supply unit. The electrodes are provided in a region inside an electrostatic chuck to positionally correspond to a focus ring. A substrate is placed on the electrostatic chuck, and a voltage for attracting and holding the focus ring is applied to the electrostatic chuck. Further, the supply unit supplies a heat transfer medium to a space between the electrostatic chuck and the focus ring that is placed on the electrostatic chuck and surrounds a region on which the substrate is placed.

### SUMMARY

The technique according to the present disclosure improves a peelability of a heat transfer sheet from a substrate support while maintaining heat transferability between an edge ring and the substrate support in a structure in which the heat transfer sheet is disposed between the edge ring and the substrate support.

In accordance with an aspect of the present disclosure, there is provided a substrate support including: a substrate support surface on which a substrate is placed; a ring support surface on which an edge ring is placed to surround the substrate placed on the substrate support surface; and an electrode configured to attract and hold the edge ring on the ring support surface by an electrostatic force. A heat transfer sheet is attached to a surface of the edge ring facing the ring support surface, and the edge ring is placed on the ring support surface via the heat transfer sheet. A conductive film is formed on a surface of the heat transfer sheet facing the ring support surface. Further, the edge ring is held on the ring support surface by attracting and holding the conductive film of the heat transfer sheet attached to the edge ring onto the ring support surface by the electrostatic force generated by the electrode.

### BRIEF DESCRIPTION OF THE DRAWINGS

The objects and features of the present disclosure will become apparent from the following description of embodiments, given in conjunction with the accompanying drawings, in which:

FIG. 1 is a plan view showing a schematic configuration of a plasma processing system according to an embodiment;

FIG. 2 is a vertical cross-sectional view showing a schematic configuration of a processing module;

FIG. 3 is a cross-sectional view showing a schematic configuration of a heat transfer sheet;

FIG. 4 shows another example of an edge ring;

FIG. 5 shows another example of a lifter pin;

FIG. 6 shows still another example of the lifter pin; and

FIG. 7 shows still another example of the edge ring.

### DETAILED DESCRIPTION

In a semiconductor device manufacturing process, a substrate such as a semiconductor wafer (hereinafter, referred to as “wafer”) is subjected to plasma processing such as etching or film formation using plasma. The plasma processing is performed in a state where the wafer is placed on a substrate support provided in a processing chamber and a pressure in the processing chamber is reduced.

Further, in order to obtain good and uniform processing results in a central portion and a peripheral portion of the substrate during the plasma processing, an edge ring may be disposed to surround a periphery of the substrate on the substrate support.

Further, since a temperature control of the substrate is important in the plasma processing, a temperature of the substrate support is adjusted by a temperature adjusting mechanism. Therefore, the substrate is controlled to have a desired temperature through the substrate support.

When the edge ring is used, a temperature control of the edge ring is also important because a temperature of the edge ring fluctuates under the influence of plasma and the temperature of the edge ring affects the plasma processing result of the peripheral portion of the substrate. Therefore, the temperature of the edge ring is also adjusted through the substrate support. However, even if a mirror surface finishing is performed on the edge ring and the substrate support, a surface of the edge ring and a surface of the substrate support have roughness. Moreover, a fine space is formed between the edge ring and the substrate support since the edge ring and the substrate support expand due to the influence of plasma. Therefore, such a space becomes a vacuum heat insulating layer when the edge ring is simply placed on the substrate support and the pressure inside the processing chamber is reduced. As a result, heat transferability between the edge ring and the substrate support becomes poor, and thus it is difficult to adjust the temperature of the edge ring to the desired temperature through the substrate support.

As a countermeasure against the above, a technique of disposing a heat transfer sheet between an edge ring and a substrate support has been proposed (see, e.g., Japanese Patent Application Publication No. 2016-119334). In particular, if the heat transfer sheet has adhesiveness and elasticity, the stability of contact between the heat transfer sheet and the edge ring and the stability of contact between the heat transfer sheet and the substrate support are increased, so that heat transferability between the edge ring and the substrate support can be improved.

However, if the heat transfer sheet has adhesiveness, when the operator removes the edge ring from the substrate support to replace the edge ring, a part of the heat transfer sheet may remain on the substrate support. This also applies to the case where the edge ring is replaced by using the lifter pin(s) that lifts the edge ring as described in Japanese Patent Application Publication No. 2011-054933. If the heat transfer sheet remains on the substrate support, additional time and effort are required to remove the heat transfer sheet.

As another technique for improving heat transferability between a substrate support and an edge ring, the substrate support includes an electrode to which a voltage for attracting and holding an edge ring by an electrostatic force is applied, and a heat transfer gas is supplied to a space between the substrate support and the edge ring (see, e.g., Japanese Patent Application Publication No. 2016-122740).

In the above configuration, there is no heat transfer sheet that would remain on the substrate support when the edge ring is replaced. However, if a gas flow of the heat transfer gas supplied to the space between the substrate support and the edge ring is large, the edge ring may be displaced. For this reason, the gas flow of the heat transfer gas has to be limited, and thus there is room for improvement in the heat transferability between the edge ring and the substrate support. Recently, the energy of plasma has been increased in order to improve the processing results of plasma processing. Therefore, in the above-described technique using the heat transfer gas, if the energy of plasma is large and heat input to the edge ring from the plasma is large, it is difficult to control the temperature of the edge ring to a desired temperature.

Accordingly, the technique according to the present disclosure improves the peelability, that is, the peeling of the heat transfer sheet from the substrate support while maintaining the heat transferability between the edge ring and the substrate support in a structure the heat transfer sheet is disposed between the edge ring and the substrate support.

Hereinafter, an edge ring, a substrate support, a plasma processing system, and a method of replacing the edge ring according to embodiments of the present disclosure will be described with reference to the accompanying drawings. Throughout the present specification and the drawings, like reference numerals will be given to like parts having substantially the same functions, and redundant description thereof will be omitted.

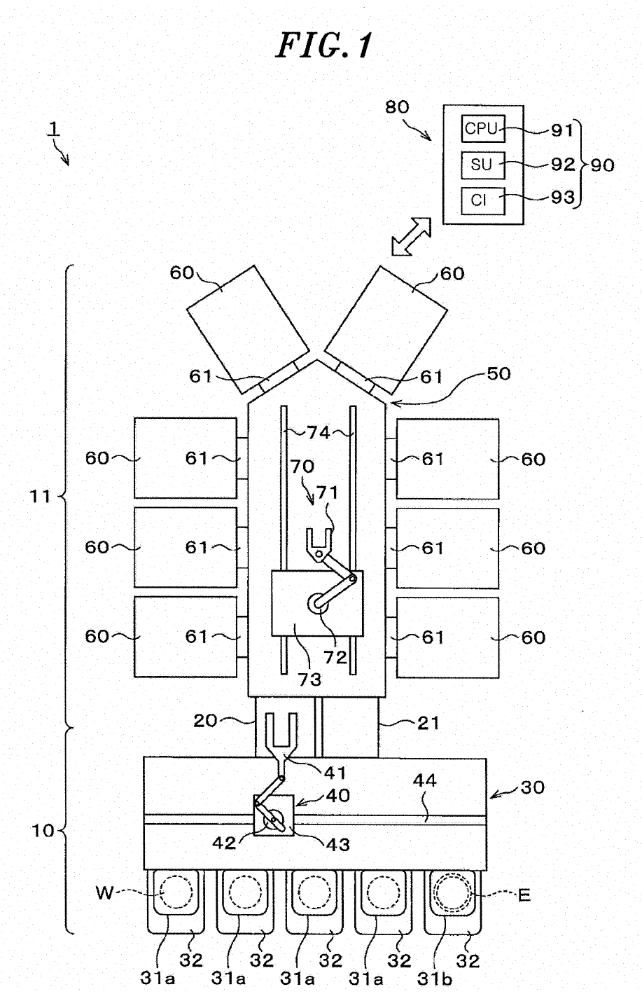

FIG. 1 is a plan view showing a schematic configuration of a plasma processing system according to an embodiment. In a plasma processing system 1 of FIG. 1, for example, a wafer W that is a substrate is subjected to plasma processing such as etching, film formation, and diffusion using plasma.

As illustrated in FIG. 1, the plasma processing system 1 has an atmospheric section 10 and a decompression section 11, and the atmospheric section 10 and the decompression section 11 are integrally connected to each other via load lock modules 20 and 21. The atmospheric section 10 includes an atmospheric module that performs desired processing on the wafer W under an atmospheric pressure atmosphere. The decompression section 11 includes a decompression module that performs desired processing on the wafer W in a pressure-reduced atmosphere.

The load lock modules 20 and 21 are connected to a loader module 30, to be described later, of the atmospheric section 10 and a transfer module 50, to be described later, of the decompression section 11 through gate valves (not shown). The load lock modules 20 and 21 are configured to temporarily hold the wafer W. Further, each of the load lock modules 20 and 21 is configured such that an inner space thereof can be switched between an atmospheric pressure atmosphere and a pressure-reduced atmosphere (vacuum atmosphere).

The atmospheric section 10 includes the loader module 30 having a transfer device 40 to be described later, and load ports 32 in which Front Opening Unified Pods (FOUPs) 31a and 31b are mounted thereon. Each FOUP 31a is configured to store a plurality of wafers W, and the FOUP 31b is configured to store a plurality of edge rings E. Moreover, an orienter module (not shown) that adjusts horizontal orientations of the wafer W and the edge ring E, and/or a storage module (not shown) that stores, for example, the plurality of wafers W may be provided to be adjacent to the loader module 30.

The loader module 30 includes a rectangular housing, and the inside of the housing is maintained in an atmospheric pressure atmosphere. A plurality of load ports 32, for example, five load ports 32, are disposed side by side on one side surface forming a long side of the housing of the loader module 30. The load lock modules 20 and 21 are disposed side by side on the other side surface forming the long side of the housing of the loader module 30.

The transfer device 40 configured to transfer the wafer W and the edge ring E is provided inside the loader module 30. The transfer device 40 has a transfer arm 41 that holds and moves the wafer W or the edge ring E, a rotor 42 that rotatably supports the transfer arm 41, and a base 43 on which the rotor 42 is placed. Further, a guide rail extending in a longitudinal direction of the loader module 30 is provided inside the loader module 30. The base 43 is provided on the guide rail 44, and the transfer device 40 is configured to be movable along the guide rail 44.

The decompression section 11 has a transfer module 50 configured to transfer the wafer W or the edge ring E, and a processing module 60 serving as a plasma processing apparatus that is configured to perform desired plasma processing on the wafer W transferred from the transfer module 50. The inside of each of the transfer module 50 and the processing module 60 is maintained in a pressure-reduced atmosphere. A plurality of processing modules 60, for example, eight processing modules, are provided for one transfer module 50. The number and arrangement of the processing modules 60 are not limited to the present embodiment and may be arbitrarily set as long as at least one processing module that requires replacement of the edge ring E is provided. Further, a storage place of the edge ring E may be provided in the decompression section 11. That is, an edge ring storage module connected to the transfer module 50 may be provided in place of the FOUP 31b or together with the FOUP 31b to store the edge ring E.

The transfer module 50 includes a polygonal (pentagonal shape in the illustrated example) housing, and the transfer module 50 is connected to the load lock modules 20 and 21 as described above. The transfer module 50 is configured to transfer the wafer W loaded into the load lock module 20 to one processing module 60, and transfer the wafer W subjected to the desired plasma processing in the processing module 60 to the atmospheric section 10 via the load lock module 21. Further, the transfer module 50 is configured to transfer the edge ring E loaded into the load lock module 20 to one processing module 60, and transfer the edge ring E that is a replacement target in the processing module 60 to the atmospheric section 10 via the load lock module 21.

For example, the processing module 60 performs plasma processing such as etching, film formation, and diffusion on the wafer W using plasma. For the processing module 60, a module that performs the desired plasma processing can be arbitrarily selected. Further, the processing module 60 is connected to the transfer module 50 through a gate valve 61. A configuration of the processing module 60 will be described later.

A transfer device 70 that is configured to transfer the wafer W or the edge ring E is provided inside the transfer module 50. The transfer device 70 includes a transfer arm 71 serving as a holder that holds and moves the wafer W or the edge ring E, a rotor 72 that rotatably supports the transfer arm 71, and a base 73 on which the rotor 72 is placed. Further, guide rails 74 that extend in a longitudinal direction of the transfer module 50 are provided inside the transfer module 50. The base 73 is provided on the guide rails 74, and the transfer device 70 is configured to be movable along the guide rails 74.

In the transfer module 50, the wafer W or the edge ring E held in the load lock module 20 is received by the transfer arm 71 and transferred into the processing module 60. Further, the wafer W or the edge ring E held in the processing module 60 is received by the transfer arm 71 and loaded into the load lock module 21.

Further, the plasma processing system 1 has a control device 80. In one embodiment, the control device 80 processes computer-executable instructions for causing the plasma processing system 1 to perform various processes described in the present disclosure. The control device 80 may be configured to control the respective components of the plasma processing system 1 to perform the various processes described herein. In one embodiment, the control device 80 may be partially or entirely included within the components of the plasma processing system 1. For example, the control device 80 may include a computer 90. For example, the computer 90 may include a processing unit (central processing unit (CPU)) 91, a storage unit (SU) 92, and a communication interface (CI) 93. The processing unit 91 may be configured to perform various control operations based on a program stored in the storage unit 92. The storage unit 92 may include a random access memory (RAM), a read only memory (ROM), a hard disk drive (HDD), a solid state drive (SSD), or a combination thereof. The communication interface 93 may communicate with the components of the plasma processing system 1 via a communication connection such as a local area network (LAN).

Next, wafer processing performed using the plasma processing system 1 configured as described above will be described.

First, the wafer W is extracted from a desired FOUP 31a by the transfer device 40 and loaded into the load lock module 20. When the wafer W is loaded into the load lock module 20, the inside of the load lock module 20 is sealed and a pressure therein is reduced. Thereafter, the inside of the load lock module 20 and the inside of the transfer module 50 communicate with each other.

Next, the wafer W is held by the transfer device 70 and transferred from the load lock module 20 to the transfer module 50.

Next, the gate valve 61 is opened, and the wafer W is loaded into a desired processing module 60 by the transfer device 70. Thereafter, the gate valve 61 is closed, and the wafer W is subjected to the desired processing in the processing module 60. The processing performed on the wafer W in the processing module 60 will be described later.

Next, the gate valve 61 is opened, and the wafer W is unloaded from the processing module 60 by the transfer device 70. Thereafter, the gate valve 61 is closed.

Next, the wafer W is loaded into the load lock module 21 by the transfer device 70. When the wafer W is loaded into the load lock module 21, the inside of the load lock module 21 is sealed and exposed to the atmosphere. Thereafter, the inside of the load lock module 21 and the inside of the loader module 30 communicate with each other.

Next, the wafer W is held by the transfer device 40, transferred from the load lock module 21 to the desired FOUP 31a via the loader module 30, and accommodated in the desired FOUP 31a. With the above procedure, a series of wafer processing steps in the plasma processing system 1 are completed.

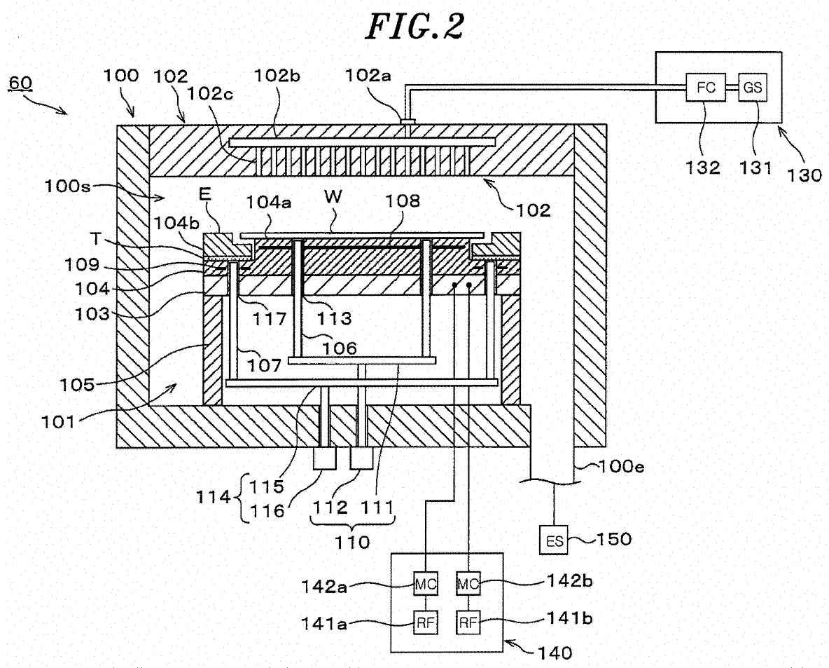

Hereinafter, the processing module 60 will be described with reference to FIG. 2. FIG. 2 is a vertical cross-sectional view showing a schematic configuration of the processing module 60.

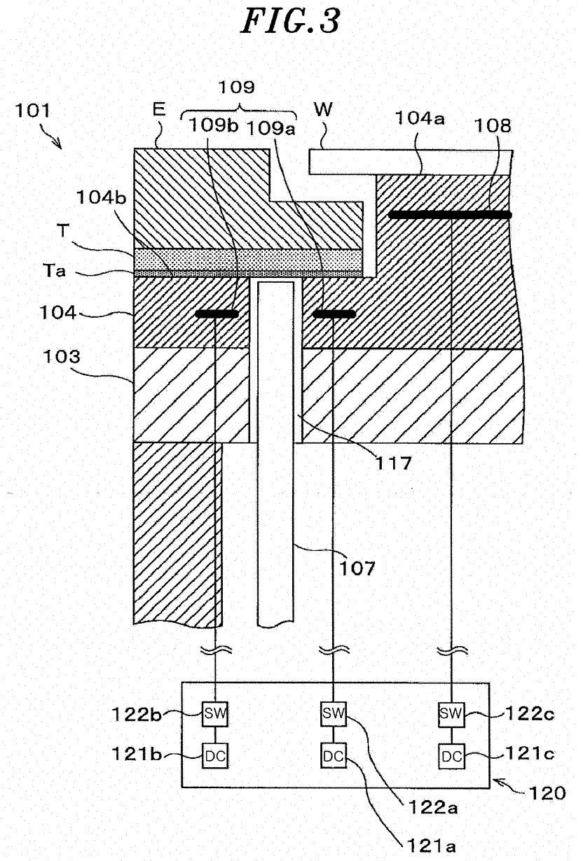

As illustrated in FIG. 2, the processing module 60 includes a plasma processing chamber 100 serving as a processing chamber, a gas supply unit 130, a radio frequency (RF) power supply unit 140, and an exhaust system (ES) 150. Further, the processing module 60 also includes a voltage application unit 120 to be described later (see, e.g., FIG. 3). Further, the processing module 60 includes a wafer support 101 serving as a substrate support and a shower head 102 serving as an upper electrode.

The wafer support 101 is disposed in a lower region of a plasma processing space 100s in the pressure-reducible plasma processing chamber 100. The shower head 102 is disposed above the wafer support 101 and may function as a portion of a ceiling of the plasma processing chamber 100.

The wafer support 101 is configured to support the wafer W in the plasma processing space 100s. In one embodiment, the wafer support 101 includes a lower electrode 103, an electrostatic chuck 104, an insulator 105, lifter pins 106, and lifter pins 107. Although not illustrated, the wafer support 101 includes a temperature control module configured to adjust at least one of the electrostatic chuck 104 and the wafer W to a target temperature. The temperature control module may include a heater, a flow path, or a combination thereof. A temperature control fluid such as a refrigerant or a heat transfer gas flows through the flow path.

The lower electrode 103 is made of, for example, a conductive material such as aluminum. In one embodiment, the temperature control module described above may be provided in the lower electrode 103.

The electrostatic chuck 104 is a member configured to attract and hold both the wafer W and the edge ring E by an electrostatic force, and is provided on the lower electrode 103. An upper surface 104a of a central portion of the electrostatic chuck 104 is formed to be higher than an upper surface 104b of a peripheral portion of the electrostatic chuck 104. The upper surface 104a of the central portion of the electrostatic chuck 104 serves as a substrate support surface on which the wafer W is placed, and the upper surface 104b of the peripheral portion of the electrostatic chuck 104 serves as a ring support surface on which the edge ring E is placed.

The edge ring E is formed in an annular shape in a plan view, and is a member disposed to surround the wafer W placed on the upper surface (hereinafter, wafer support surface) 104a of the central portion of the electrostatic chuck 104. The edge ring E is placed on the ring support surface 104b via a heat transfer sheet T. Specifically, the edge ring E is placed on the ring support surface 104b in a state in which the heat transfer sheet T is attached, in advance, to be integrally formed with a lower surface of the edge ring E that faces the upper surface (hereinafter, the ring support surface) 104b of the peripheral portion of the electrostatic chuck 104.

An electrode 108 for attracting and holding the wafer W is provided in the central portion of the electrostatic chuck 104, and an electrode 109 for attracting and holding the edge ring E is provided in the peripheral portion of the electrostatic chuck 104. The electrostatic chuck 104 has a structure in which the electrodes 108 and 109 are sandwiched between insulators made of an insulating material. A voltage is applied to each of the electrodes 108 and 109 from the voltage application unit 120 (see FIG. 3) so as to generate an electrostatic force for attracting and holding the wafer W and the edge ring E.

In the present embodiment, the central portion of the electrostatic chuck 104 provided with the electrode 108, and the peripheral portion of the electrostatic chuck 104 provided with the electrode 109 are integrally formed as a single body, but the central portion and the peripheral portion may be formed as separate bodies.

Further, for example, the central portion of the electrostatic chuck 104 is formed to have a diameter smaller than a diameter of the wafer W. Thus, when the wafer W is placed on the wafer support surface 104a, the peripheral portion of the wafer W is horizontally protrudes from the central portion of the electrostatic chuck 104.

Although not illustrated, the wafer support surface 104a of the electrostatic chuck 104 is formed with a gas supply hole(s) in order to supply a heat transfer gas to a bottom (back) surface of the wafer W placed on the wafer support surface 104a. Through the gas supply hole, the Heat transfer gas from a gas supply unit (not shown) is supplied. The gas supply unit may include one or more gas sources and one or more flow controllers. In one embodiment, for example, the gas supply unit is configured to supply the heat transfer gas from the gas source to the heat transfer gas supply hole via the flow controller. For example, each flow controller may include a mass flow controller or a pressure-control type flow controller.

As described above, the wafer support surface 104a of the electrostatic chuck 104 is formed with the heat transfer gas supply hole(s). However, the ring support surface 104b is not formed with the heat transfer gas supply hole(s).

The edge ring E placed on the ring support surface 104b has a stepped portion formed on an upper portion thereof, and an upper surface of an outer peripheral portion of the edge ring E is formed to be higher than an upper surface of an inner peripheral portion of the edge ring E. The inner peripheral portion of the edge ring E is formed so as to enter an area below the peripheral portion of the wafer W horizontally protruding from the central portion of the electrostatic chuck 104. In other words, an inner diameter of the edge ring E is formed to be smaller than an outer diameter of the wafer W.

Further, for example, quartz is used as the material of the edge ring E. Alternatively, silicon (Si) or silicon carbide (SiC) may be used as the material of the edge ring E.

The insulator 105 is a cylindrical member made of ceramic or the like, and supports the electrostatic chuck 104. For example, the insulator 105 is formed so as to have an outer diameter equal to an outer diameter of the lower electrode 103, and supports a peripheral portion of the lower electrode 103.

Each lifter pin 106 is a columnar member that is raised or lowered (vertically moved) to protrude beyond or retract below the wafer support surface 104a of the electrostatic chuck 104. The lifter pin 106 is made of, for example, ceramic. Three or more lifter pins 106 are provided at intervals along a circumferential direction of the electrostatic chuck 104, that is, a circumferential direction of the wafer support surface 104a. For example, the lifter pins 106 are provided at equal intervals along the circumferential direction. The lifter pins 106 are provided so as to extend in the vertical direction.

The lifter pins 106 are connected to a lifting mechanism 110 that vertically moves the lifter pins 106. For example, the lifting mechanism 110 includes a support member 111 that supports the lifter pins 106, and a driving unit 112 that generates a driving force for vertically moving the support member 111 to vertically move the lifter pins 106. The driving unit 112 has a motor (not shown) that generates the driving force.

Each of the lifter pins 106 is inserted into a through-hole 113 that extends downward from the wafer support surface 104a of the electrostatic chuck 104 to reach a bottom surface of the lower electrode 103. In other words, the through-hole 113 is formed through the central portion of the electrostatic chuck 104 and the lower electrode 103.

Each lifter pin 107 is a columnar member that is raised or lowered (vertically moved) to protrude beyond or retract below the ring support surface 104b of the electrostatic chuck 104. The lifter pin 107 is made of, for example, alumina, quartz, SUS, or the like. Three or more lifter pins 107 are provided at intervals along the circumferential direction of the electrostatic chuck 104, that is, the circumferential direction of the ring mounting surface 104b. For example, the lifter pins 107 are provided at equal intervals along the circumferential direction. The lifter pins 107 are provided so as to extend in the vertical direction, and position upper end surfaces thereof are to be horizontally flat.

Further, for example, a thickness of each lifter pin 107 is in a range from 1 mm to 3 mm.

The lifter pins 107 are connected to a lifting mechanism 114 that drives the lifter pins 107. For example, the lifting mechanism 114 includes a support member 115 that supports the lifter pins 107, and a driving unit 116 that generates a driving force for vertically moving the support member 115 to vertically move the lifter pins 107. The driving unit 116 has a motor (not shown) that generates the driving force.

Each of the lifter pins 107 is inserted into a through-hole 117 that extends downward from the ring support surface 104b of the electrostatic chuck 104 to reach the bottom surface of the lower electrode 103. In other words, the through-hole 117 is formed through the peripheral portion of the electrostatic chuck 104 and the lower electrode 103.

The shower head 102 serving as the upper electrode is configured to supply one or more processing gases from the gas supply unit 130 to the plasma processing space 100s. In one embodiment, the shower head 102 has a gas inlet 102a, a gas diffusion chamber 102b, and a plurality of gas outlets 102c. For example, the gas inlet 102a is in fluid communication with the gas supply unit 130 and the gas diffusion chamber 102b. The plurality of gas outlets 102c is in fluid communication with the gas diffusion chamber 102b and the plasma processing space 100s. In one embodiment, the shower head 102 is configured to supply one or more processing gases from the gas inlet 102a to the plasma processing space 100s via the gas diffusion chamber 102b and the plurality of gas outlets 102c.

The gas supply unit 130 may include one or more gas sources (GS) 131 and one or more flow controllers (FC) 132. In one embodiment, for example, the gas supply unit 130 is configured to supply one or more processing gases from the corresponding gas sources 131 to the gas inlet 102a via the corresponding flow controllers 132. For example, each flow controller 132 may include, for example, a mass flow controller or a pressure-control type flow controller. Further, the gas supply unit 130 may include one or more flow modulation devices that modulate or pulsate a gas flow of one or more processing gases.

The RF power supply unit 140 is configured to supply RF power, for example, one or more RF signals, to one or more electrodes such as the lower electrode 103, the shower head (upper electrode) 102, or both the lower electrode 103 and the shower head 102. Therefore, plasma is generated from one or more processing gases supplied to the plasma processing space 100s. Accordingly, the RF power supply unit 140 may function as at least a part of a plasma generation unit configured to generate plasma from one or more processing gases in the plasma processing chamber. For example, the RF power supply unit 140 includes two RF generation units (RF) 141a and 141b and two matching circuits (MC) 142a and 142b. In one embodiment, the RF power supply unit 140 is configured to supply a first RF signal from a first RF generation unit (RF) 141a to the lower electrode 103 via a first matching circuit 142a. For example, the first RF signal may have a frequency in a range of 27 MHz to 100 MHz.

Further, in one embodiment, the RF power supply unit 140 is configured to supply a second RF signal from a second RF generation unit (RF) 141b to the lower electrode 103 via a second matching circuit 142b. For example, the second RF signal may have a frequency in a range of 400 kHz to 13.56 MHz. Alternatively, a direct current (DC) pulse generation unit may be used in place of the second RF generation unit 141b.

Further, although not illustrated, other embodiments may be considered in the present disclosure. For example, in an alternative embodiment, the RF power supply unit 140 may be configured to supply the first RF signal from the RF generation unit to the lower electrode 103, the second RF signal from another RF generation unit to the lower electrode 103, a third RF signal from still another RF generation unit to the lower electrode 103. In addition, in another alternative embodiment, a DC voltage may be applied to the shower head 102.

Further, in various embodiments, amplitudes of one or more RF signals (that is, first RF signal, second RF signal, and the like) may be pulsated or modulated. The amplitude modulation may include pulsating the RF signal amplitude between an ON state and an OFF state, or between two or more different ON states.

The exhaust system 150 may be connected to, for example, an exhaust port 100e disposed at a bottom of the plasma processing chamber 100. The exhaust system 150 may include a pressure valve and a vacuum pump. The vacuum pump may include a turbo molecular pump, a roughing pump or a combination thereof.

Next, the heat transfer sheet T and the voltage application unit 120 will be described with FIG. 3. FIG. 3 is a cross-sectional view showing a schematic configuration of the heat transfer sheet T.

The heat transfer sheet T is a sheet-shaped member, and, similar to the edge ring E, the heat transfer sheet T has an annular shape in a plan view. Specifically, the heat transfer sheet T has the annular shape having an outer diameter that is smaller than an outer diameter of the edge ring E and an inner diameter that is smaller than an inner diameter of the edge ring E.

Further, the heat transfer sheet T is formed to have high thermal conductivity of, for example, 0.2 to 5 W/m·K and high elasticity. For example, in the heat transfer sheet T, a heat-resistant organic material is used as a base material, and a large number of heat transfer fillers are mixed and dispersed. The heat-resistant organic material may be, for example, a heat-resistant adhesive or rubber containing silicon. Further, the heat transfer filler is, for example, alumina particle-based.

For example, the heat transfer sheet T has a gel-like property and adhesiveness when it is attached to the edge ring E, and the heat transfer sheet T is attached to the edge ring E due to its adhesiveness (adhesivity).

Further, as shown in FIG. 3, the heat transfer sheet T has a conductive film Ta formed on a surface thereof facing the ring support surface 104b.

The conductive film Ta is a film formed of a conductive material such as a metal material. As an example of the metal material, aluminum (Al), which is the same as the material of the plasma processing chamber 100, specifically, the material of side walls and a bottom wall of the plasma processing chamber 100, is used in order to avoid contamination of the wafer W and the plasma processing chamber 100.

A method of forming the conductive film Ta on the heat transfer sheet T is, for example, a method of attaching a metal foil made of a metal material by the adhesiveness (adhesivity) of the heat transfer sheet T. The conductive film Ta may be formed by sputtering or vapor deposition. Further, the conductive film Ta may be formed on the heat transfer sheet T before the heat transfer sheet T is attached to the edge ring E or after the heat transfer sheet T is attached to the edge ring E.

Further, the conductive film Ta is a thin film having a thickness of, for example, 10 μm or less, and is preferably formed to be the thinnest within a formable range. As described above, since the conductive film Ta is thin, the conductive film is plastically deformed when the edge ring E is attracted. Therefore, no gap is formed between the conductive film Ta and the ring support surface 104b. Further, the conductive film Ta preferably has a thermal conductivity equal to or higher than the thermal conductivity of the heat transfer sheet T. However, if the conductive film Ta is formed to be as thin as possible as described above, the conductive film Ta may have a thermal conductivity higher than the thermal conductivity of the heat transfer sheet T.

The edge ring E to which the heat transfer sheet T is attached is attracted and held onto the ring support surface 104b by the electrostatic force generated between the conductive film Ta formed on the heat transfer sheet T and the electrode 109.

The electrode 109 is, for example, a bipolar electrode including a pair of electrodes 109a and 109b. The voltage application unit 120 is provided for the electrodes 109a and 109b.

The voltage application unit 120 includes, for example, two DC power supplies (DC) 121a and 121b and two switches (SW) 122a and 122b.

The DC power supply 121a is connected to the electrode 109a via the switch 122a, and a positive voltage or a negative voltage for attracting and holding the edge ring E is selectively applied to the electrode 109a from the DC power supply 121a. The DC power supply 121b is connected to the electrode 109b via the switch 122b, and a positive voltage or a negative voltage for attracting and holding the edge ring E is selectively applied to the electrode 109b from the DC power supply 121b.

Further, the voltage application unit 120 includes, for example, a DC power supply (DC) 121c and a switch (SW) 122c.

The DC power supply 121c is connected to the electrode 108 via the switch 122c, and a voltage for attracting and holding the wafer W is applied to the electrode 108 from the DC power supply 121c.

In the present embodiment, although the case where the electrode 109 for attracting and holding the edge ring E is the bipolar electrode is described, the electrode 109 may be a monopolar electrode.

Further, in the present embodiment, although the case where the electrode 109 is provided in the electrostatic chuck 104 to attract and hold the edge ring E by the electrostatic force is described, for example, a DC voltage may be also applied to the lower electrode 103 to attract and hold the edge ring E by an electrostatic force thus generated.

Next, an example of wafer processing performed by using the processing module 60 will be described. The processing module 60 performs processing such as etching, film formation, and diffusion on the wafer W.

First, the wafer W is loaded into the plasma processing chamber 100, and the wafer W is placed on the electrostatic chuck 104 by vertically moving the lifter pins 106. Thereafter, a DC voltage is applied to the electrode 108 of the electrostatic chuck 104 from the DC power supply 121c, and thus the wafer W is electrostatically attracted and held onto the electrostatic chuck 104 by electrostatic force. Further, after the wafer W is loaded, the pressure inside the plasma processing chamber 100 is reduced to a predetermined vacuum level by the exhaust system 150.

Next, the processing gas is supplied from the gas supply unit 130 to the plasma processing space 100s via the shower head 102. Further, RF power HF for plasma generation is supplied from the RF power supply unit 140 to the lower electrode 103, and thus the processing gas is excited to generate plasma. Further, RF power LF for ion attraction may be supplied from the RF power supply unit 140. Then, the wafer W is subjected to plasma processing by the action of the generated plasma.

In order to end the plasma processing, the supply of the RF power HF from the RF power supply unit 140 and the supply of the processing gas from the gas supply unit 130 are stopped. If the RF power LF is supplied during the plasma processing, the supply of the RF power LF is also stopped. Next, the supply of the DC voltage from the DC power supply 121c is stopped, and the attracting and holding of the wafer W on the electrostatic chuck 104 is stopped.

Thereafter, the wafer W is raised by the lifter pins 106 and separated from the electrostatic chuck 104. During the separation, charge neutralization of the wafer W may be performed. Then, the wafer W is unloaded from the plasma processing chamber 100, and a series of wafer processing steps are completed.

Further, the edge ring E is attracted and held by the electrostatic force during the wafer processing, and specifically, the edge ring E is attracted and held by the electrostatic force even during the plasma processing and before and after the plasma processing. Before and after the plasma processing, different voltages are applied to the electrodes 109a and 109b from the DC power supply 121a and the DC power supply 121b, respectively, such that a potential difference is generated between the electrodes 109a and 109b. The edge ring E is attracted and held by the electrostatic force caused by the potential difference. In contrast, during the plasma processing, the same voltage (for example, the same positive voltage) is applied to the electrode 109a and the electrode 109b from the DC power supply 121a and the DC power supply 121b, and a potential difference is generated between the electrode 109a/the electrode 109b and the edge ring E having a ground potential through the plasma. The edge ring E is attracted and held by the electrostatic force caused by the potential difference. Further, while the edge ring E is attracted and held by the electrostatic force, the lifter pins 107 are retracted below the ring support surface 104b of the electrostatic chuck 104.

Next, an example of a process of placing the edge ring E in the processing module 60 that is performed using the above-described plasma processing system 1 will be described. The following processing is performed under the control of the control device 80. Further, in the following description, the edge ring E to which the heat transfer sheet T is attached in advance may be referred to as a replacement edge ring E, and the replacement edge ring E excluding the heat transfer sheet T may be referred to as an edge ring body.

First, the transfer arm 71 holding the replacement edge ring E is inserted into the pressure-reduced plasma processing chamber 100 through the loading/unloading port (not shown), and the replacement edge ring E is delivered to a position above the ring support surface 104b of the electrostatic chuck 104.

Next, the lifter pins 107 are raised, and the replacement edge ring E is transferred from the transfer arm 71 to the lifter pins 107.

Subsequently, the transfer arm 71 is extracted (retracted) from the plasma processing chamber 100, and the lifter pins 107 are lowered. Thus, the replacement edge ring E is placed on the ring support surface 104b of the electrostatic chuck 104.

Thereafter, a DC voltage from the voltage application unit 120 is applied to the electrode 109 provided in the peripheral portion of the electrostatic chuck 104, and the conductive film Ta of the heat transfer sheet T being attached to the replacement edge ring E is attracted and held on the ring support surface 104b by the electrostatic force generated by the applied DC voltage. Specifically, different voltages are applied from the DC power supplies 121a and 121b to the electrodes 109a and 109b, respectively, and the conductive film Ta of the heat transfer sheet T attached to the replacement edge ring E is attracted and held on the ring support surface 104b by the electrostatic force caused by the potential difference. As a result, the replacement edge ring E is attracted and held on the ring support surface 104b. With the above procedure, a series of processes of placing the edge ring E are completed.

A process of removing the replacement edge ring E is performed in the reverse order of the process of placing the replacement edge ring E described above. At the time of removing the replacement edge ring E, since the heat transfer sheet T is formed with the conductive film Ta, the surface of the replacement edge ring E in contact with the ring support surface 104b does not have the adhesiveness. Therefore, the heat transfer sheet T does not remain on the ring support surface 104b when the replacement edge ring E is raised by the lifter pins 107.

Moreover, when the replacement edge ring E is removed, the replacement edge ring E may be cleaned and then unloaded from the plasma processing chamber 100.

Further, the transfer of the replacement edge ring E between the FOUP 31b and the processing module 60 requiring the replacement of the edge ring E at the time of placing or removing the replacement edge ring E is performed in the same manner as the transfer of the wafer W between the FOUP 31a and the processing module 60 at the time of the above-described wafer processing.

As described above, the wafer support 101 according to the present embodiment includes the wafer support surface 104a on which the wafer W is placed, the ring support surface 104b on which the edge ring E is placed to surround the wafer W placed on the wafer support surface 104a, and the electrode 109 for attracting and holding the edge ring E onto the ring support surface 104b by the electrostatic force. Further, the heat transfer sheet T is attached to the surface of the edge ring E facing the ring support surface 104b, and the edge ring E is placed on the ring support surface 104b with the heat transfer sheet T interposed therebetween. Further, the conductive film Ta is formed on the surface of the heat transfer sheet T facing the ring support surface 104b. Therefore, the heat transfer sheet T has adhesiveness only on the surface thereof facing the edge ring E and has no adhesiveness on the contact surface with the ring support surface 104b. Accordingly, when the edge ring E is separated from the ring support surface 104b, the heat transfer sheet T is also removed together with the edge ring E from the ring support surface 104b, so that the heat transfer sheet T does not remain on the ring support surface 104b. Further, in the present embodiment, the edge ring E is placed and held on the ring support surface 104b of the wafer support 101 by attracting and holding the conductive film Ta of the heat transfer sheet T attached to the edge ring E onto the ring support surface 104b by the electrostatic force generated by the electrode 109. Therefore, the conductive film Ta is pressed against the ring support surface 104b and deformed by the electrostatic force, so that the conductive film Ta and the ring support surface 104b are in close contact with each other without a gap therebetween. Accordingly, forming the conductive film Ta does not deteriorate the heat transferability between the edge ring E and the wafer support 101.

As described above, according to the present embodiment, the peelability, that is, the peeling of the heat transfer sheet T from the wafer support 101 is improved while the heat transferability between the edge ring E and the wafer support 101 with the heat transfer sheet T interposed therebetween is maintained.

In the case where the heat transfer gas is used as disclosed in Japanese Patent Application Publication No. 2016-122740, the edge ring may not be controlled to have a desired temperature when the large amount of heat is input from the plasma to the edge ring. This is because, in the above case, the edge ring and the wafer support expand greatly due to the heat input, thereby forming the large gap therebetween. Thus, the electrostatic force acting on the edge ring is weakened, which leads to the leakage of the heat transfer gas and the deterioration of the heat transferability between the edge ring and the wafer support. On the other hand, in the present embodiment, the heat transfer gas is not used, and even when the edge ring E and the wafer support 101 greatly expand due to heat input from the plasma, the heat transfer sheet T and the conductive film Ta can follow the expansion. Therefore, no gap is formed between the edge ring E and the wafer support 101, so that the edge ring E can be controlled to have a desired temperature through the wafer support 101.

For the heat transfer gas, for example, a helium gas is used. However, the helium gas is expensive. In the present embodiment, since such an expensive helium gas is not used, the cost reduction can be realized.

Further, according to the present embodiment, even when the edge ring E is replaced by controlling the lifter pins 107 and the transfer device 70, the heat transfer sheet does not remain on the ring support surface 104b of the wafer support 101. In other words, according to the present embodiment, the edge ring E can be automatically replaced without the manual operation performed by the operator.

Further, in the present embodiment, the gas supply hole for supplying the heat transfer gas is not formed on the ring support surface 104b. Therefore, the contact area of the ring support surface 104b with respect to the edge ring E is large, so that the improved heat transferability can be obtained between the edge ring E and the wafer support 101. When the through-hole 117 through which the lifter pin 107 is inserted is not provided and the edge ring E is manually replaced by the operator, the heat transferability between the edge ring E and the wafer support 101 can be further improved since the contact area of the ring support surface 104b with respect to the edge ring E is further increased.

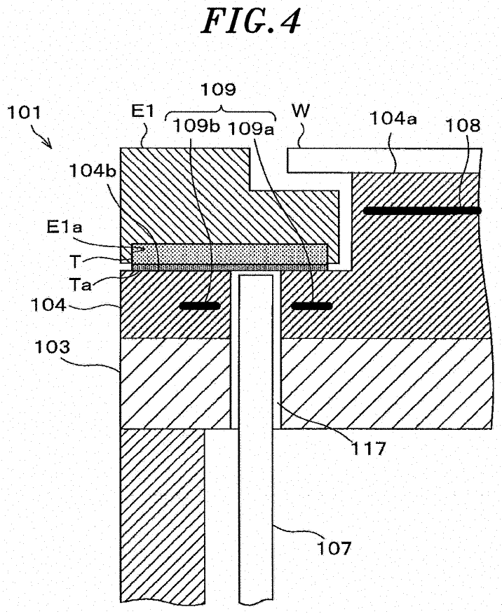

Further, in the present embodiment, the edge ring E is electrostatically attracted and held by using the conductive film Ta of the heat transfer sheet T attached to the edge ring E. Therefore, an insulating material such as quartz can be used as the material of the edge ring E. FIG. 4 shows another example of the edge ring.

An edge ring E1 of FIG. 4 has a recess E1a on a surface thereof facing the ring support surface 104b. The recess E1a is recessed in a direction away from the ring support surface 104b, and the heat transfer sheet T is affixed to the recess E1a.

With this configuration, the side area of the heat transfer sheet T exposed to the plasma processing space 100s is reduced. Therefore, it is possible to prevent the heat transfer sheet T from being damaged by the plasma.

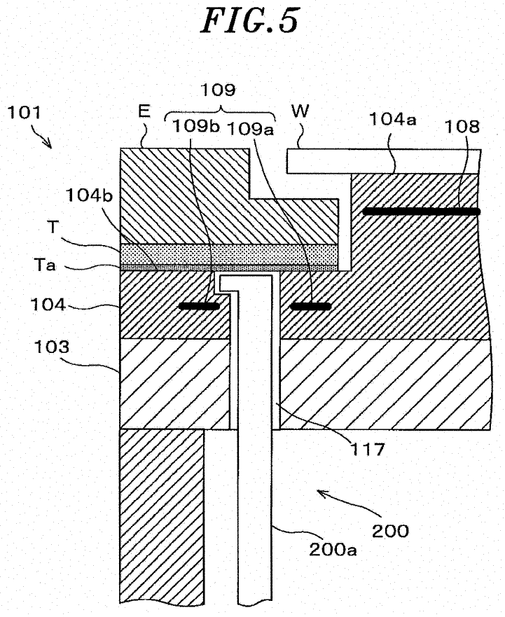

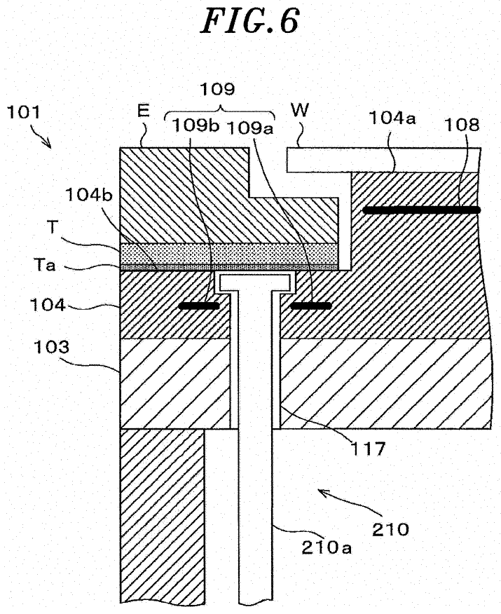

FIGS. 5 and 6 show other examples of the lifter pin.

Lifter pins 200 and 210 of FIGS. 5 and 6 have columnar body portions 200a and 210a, each of which has a circular cross section or a polygonal cross section and extends in the vertical direction in a side view, and also have contact surfaces with the edge ring E, i.e., upper end surfaces of the lifter pins 200 and 210 that are formed to have areas larger than the areas of horizontal cross sections of the columnar body portions 200a or 210a, respectively. In other words, the lifter pins 200 and 210 respectively have the larger upper end surfaces that come into contact with the edge ring (specifically, the upper end surfaces that come into contact with the heat transfer sheet T integrated with the edge ring E) as compared with the lifter pin 107 shown in FIG. 2.

The lifter pin 200 is formed into an L-shape that is turned upside down in a side view, so that the upper end surface thereof is formed to be larger than the lower portion thereof. The lifter pin 210 is formed into a T-shape in a side view, so that the upper end surface thereof is formed to be large.

Since the lifter pins 200 and 210 are respectively formed to have the larger upper end surfaces, it is possible to prevent the heat transfer sheet T from being damaged when the lifter pins 200 and 210 are raised.

The upper end of the lifter pin may be formed in an annular shape in a plan view such that an inner diameter of the lifter pin is larger than an inner diameter of the edge ring E and an outer diameter of the lifter pin is smaller than an outer diameter of the edge ring E.

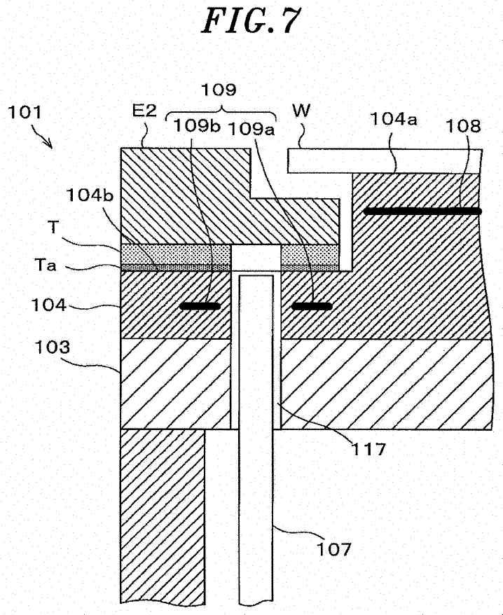

FIG. 7 shows still another example of the edge ring.

The edge ring E2 of FIG. 7 has no heat transfer sheet T and no conductive film Ta on a portion of the surface of the edge ring facing the ring support surface 104b, the portion being brought into contact with the lifter pin 107.

With this configuration, it is possible to prevent the heat transfer sheet T and the conductive film Ta from being damaged by the lifter pin 107.

While various embodiments have been described above, various omissions, substitutions, and changes may be made without being limited to the above-described embodiments. It is also possible to combine elements in different embodiments to form other embodiments.

1. A substrate support comprising:
a substrate support surface on which a substrate is placed;
a ring support surface on which an edge ring is placed to surround the substrate placed on the substrate support surface; and
an electrode configured to attract and hold the edge ring on the ring support surface by an electrostatic force,
wherein a heat transfer sheet is attached to a surface of the edge ring facing the ring support surface, and the edge ring is placed on the ring support surface via the heat transfer sheet,
a conductive film is formed on a surface of the heat transfer sheet facing the ring support surface, and
the edge ring is held on the ring support surface by attracting and holding the conductive film of the heat transfer sheet attached to the edge ring onto the ring support surface by the electrostatic force generated by the electrode.

2. The substrate support of claim 1, wherein the ring support surface has no gas supply hole for supplying a heat transfer gas.

3. The substrate support of claim 1, wherein the edge ring has a recess on the surface facing the ring support surface, and the heat transfer sheet is affixed to the recess.

4. The substrate support of claim 1, wherein the edge ring is formed of quartz.

5. The substrate support of claim 1, wherein the edge ring is formed of Si or SiC.

6. The substrate support of claim 1, wherein the conductive film is formed of Al.

7. The substrate support of claim 1, wherein a thickness of the conductive film is 10 μm or less.

8. The substrate support of claim 1, further comprising:
a lifter pin configured to vertically move the edge ring.

9. The substrate support of claim 8, wherein the lifter pin has a columnar body portion extending in a vertical direction and a contact surface with the edge ring that has an area larger than a cross-sectional area of the columnar body portion.

10. The substrate support of claim 8, wherein the edge ring has no heat transfer sheet and no conductive film on a portion of the surface of the edge ring facing the ring support surface, the portion being brought into contact with the lifter pin.

11. A plasma processing system comprising:
a plasma processing apparatus configured to perform plasma processing on the substrate placed on the substrate support, the plasma processing apparatus including the substrate support of claim 8, a pressure-reducible processing chamber having therein the substrate support, a voltage application unit configured to apply a voltage to the electrode, and a lifting mechanism configured to vertically move the lifter pin;
a transfer device having a holder configured to hold the edge ring, the transfer device being configured to insert and retract the holder into and from the processing chamber to load and unload the edge ring into and from the processing chamber; and
a control device configured to control the voltage application unit, the lifting mechanism, and the transfer device,
wherein the control device controls the voltage application unit, the lifting mechanism, and the transfer device to execute
delivering the edge ring held by the holder to a position above the substrate support;
raising the lifter pin and transferring the edge ring from the holder to the lifter pin;
lowering the lifter pin after the holder is retracted and placing the edge ring on the ring support surface via the heat transfer sheet attached to the edge ring; and
applying the voltage to the electrode and attracting and holding the conductive film of the heat transfer sheet attached to the edge ring by the electrostatic force generated by the applied voltage to hold the edge ring on the ring support surface.

12. A method of replacing an edge ring in a plasma processing apparatus including
a pressure-reducible processing chamber, and
a substrate support disposed inside the processing chamber, the substrate support including
a substrate support surface on which a substrate is placed;
a ring support surface on which the edge ring is placed to surround the substrate placed on the substrate support surface;
an electrode configured to attract and hold the edge ring on the ring support surface by an electrostatic force; and
a lifter pin configured to vertically move the edge ring, wherein an adhesive heat transfer sheet is attached to a surface of the edge ring facing the ring support surface the edge ring and a conductive film is formed on a surface of the heat transfer sheet facing the ring support surface,
the method comprising:
delivering the edge ring held by a holder of a transfer device to a position above the substrate support;
raising the lifter pin and transferring the edge ring from the holder to the lifter pin;
lowering the lifter pin after the holder is retracted and placing the edge ring on the ring support surface via the heat transfer sheet attached to the edge ring; and
applying the voltage to the electrode and attracting and holding the conductive film of the heat transfer sheet attached to the edge ring by the electrostatic force generated by the applied voltage to hold the edge ring on the ring support surface.

13. An edge ring that is placed on a substrate support disposed inside a plasma processing apparatus, which is provided for performing plasma processing on a substrate, to surround the substrate placed on the substrate support, the edge ring comprising:
a ring body formed in an annular shape in a plan view; and
a heat transfer sheet that is formed in an annular shape in a plan view and is interposed between the ring body and the substrate support when the edge ring is placed on the substrate support,
wherein the ring body is integrated with the heat transfer sheet that is attached in advance to a surface of the ring body facing the substrate support, and
the heat transfer sheet has a conductive film on a surface thereof facing the substrate support.
